(19) United States
(12) Patent Application Publication
(10) Pub. No.: US 2015/0263056 A1
(43) Pub. Date: Sep. 17, 2015

(54) STRUCTURES AND METHODS OF FORMING PHOTODIODE ARRAYS HAVING THROUGH-SEMICONDUCTOR VIAS

(71) Applicant: Aeroflex Colorado Springs Inc., Colorado Springs, CO (US)

(72) Inventor: Gerald Reinsma, Colorado Springs, CO (US)

(73) Assignee: Aeroflex Colorado Springs Inc., Colorado Springs, CO (US)

(21) Appl. No.: 14/207,006

(22) Filed: Mar. 12, 2014

(51) Int. Cl. H01L 27/146; H01L 31/0288

(52) U.S. Cl. CPC H01L 27/14636; H01L 27/14694; H01L 27/14683; H01L 27/14663; H01L 31/0288

(57) ABSTRACT

A semiconductor structure includes a through-semiconductor via having an insulating lining isolating a conductive center region of the through-semiconductor via from the surrounding semiconductor, and wherein the cross-sectional profile of the through-semiconductor via has a varying taper angle such that the diameter of the through-semiconductor via is at its narrowest at a location between two essentially parallel surfaces of the semiconductor structure.

### BACKGROUND OF THE INVENTION

Through-semiconductor vias are known in the art. They have particular advantage in certain semiconductor devices such as photodiode arrays, wherein the functionality of the array mandates that there be a connection between a front-side of a semiconductor structure and the back-side of the semiconductor structure.

A first semiconductor structure 200 including a through-semiconductor via is shown in FIG. 1. A substrate 204 and epitaxial layer 202 are shown. A straight conductive through-semiconductor via 206 is shown having oxide sidewalls 208 that isolate the center conductive portion of the via from the surrounding semiconductor structure.

A second semiconductor structure 300 including a through-semiconductor via is shown in FIG. 2. A substrate 304 and epitaxial layer 302 are shown. A tapered conductive through-semiconductor via 306 is shown having oxide sidewalls 308 that isolate the center conductive portion of the via from the surrounding semiconductor structure. Note that the via in FIG. 2 tapers from a widest width at the top-side of the semiconductor structure down to a narrowest width at the bottom-side of the semiconductor structure.

A third semiconductor structure 400 including a through-semiconductor via is shown in FIG. 3. A substrate 404 and epitaxial layer 402 are shown. A conductive through-semiconductor via is shown having a first narrow portion 406A and a second wider portion 406B. Oxide sidewalls 408 isolate the center conductive portions of the via from the surrounding semiconductor structure.

One issue with forming through-semiconductor vias is that the process must be done gradually sometimes in many process steps such that the via is properly filled with conductive material. This adds to the processing time and cost of fabricating the overall semiconductor structure, such as a photodiode array. What is desired is a method and corresponding structure for a through-semiconductor via that minimizes the number of processing steps, processing time, and associated cost.

### BRIEF DESCRIPTION OF THE DRAWINGS

The accompanying drawings, which are included to provide a further understanding of the invention and are incorporated in and constitute a part of this specification, illustrate embodiments of the invention and together with the description, serve to explain the principles of the invention.

In the Drawings:

FIGS. 1-3 are cross-sectional views of prior art through-semiconductor vias;

FIGS. 4-9 are cross-sectional views of a through-semiconductor via according to an embodiment of the present invention corresponding to sequential processing steps; and

FIG. 10 is a cross-sectional view of a completed through-semiconductor via according to an embodiment of the present invention.

### SUMMARY OF THE INVENTION

According to the present invention, structures and methods of forming photodiode arrays are presented having through-semiconductor vias with varying taper angles with respect to the front and back surfaces of the photodiode, such that the narrowest diameter of the through-semiconductor via occurs between the front and back surface of the semiconductor. This structure has benefits for depositing the center conductor of the through-semiconductor via compared to the current state of the art. In an embodiment of this invention, the narrowest diameter of the through-semiconductor via occurs approximately half-way between the front and back surface of the photodiode. Due to the way in which chemical vapor deposited films are formed, it is desirable that this center region of the through-semiconductor via be completely filled before the top or bottom openings are filled. Depending upon the taper angle between the via side-wall and the front and back surfaces, the invention allows for longer deposition times before chemical-mechanical polishing (CMP) of the deposited center conductor material from the front and/or back surfaces is necessary in order to keep such via openings sufficiently wide to allow for the gas molecules used in the CVD deposition to penetrate the opening and diffuse sufficiently far into the via to form a continuous, conducting film in the via. The present invention allows for fewer such deposition/CMP steps for a given via critical dimension (i.e. the smallest dimension for vias that are not circular nor square, or the diameter or side dimension for vias that are circular or square respectively), resulting in shorter cycle time and lower cost.

A front-side illuminated, back-side contacted photodiode structure includes a semiconductor having two essentially parallel surfaces wherein at least one of the two essentially parallel surfaces has a plurality of regions of a first conductivity type, and wherein the second surface has a single region of a conductivity type opposite to the first surface, and wherein the plurality of regions of the first conductivity type are electrically contacted by through-semiconductor vias having an insulating lining isolating the conductive center region of the through-semiconductor via from the surrounding semiconductor, and wherein the cross-sectional profile of the through-semiconductor via has a varying taper angle with respect to each of the two surfaces such that the diameter of the through-semiconductor via is at its narrowest at a location between the two essentially parallel surfaces.

The semiconductor can comprise silicon, germanium, or gallium arsenide. The plurality of regions of a first conductivity type are p-type and comprise a plurality of photodiode anodes. The plurality of photodiode anodes are comprised of silicon doped with boron. The plurality of regions of a first conductivity type are n-type and comprise a plurality of photodiode cathodes. The plurality of photodiode cathodes are comprised of silicon doped with a combination of arsenic and phosphorus. The single region of a conductivity type opposite to the first conductivity type is n-type and comprises a common photodiode cathode. The common photodiode cathode is comprised of silicon doped with a combination of arsenic and phosphorous. The single region of a conductivity type opposite to the first conductivity type is p-type and comprises a common photodiode anode. The conductive center region of the through-semiconductor via is comprised of n-type polysilicon. The n-type polysilicon is comprised of phosphorous doped polysilicon. The narrowest diameter of the through-semiconductor via occurs at a location approximately equi-distant from the two essentially parallel surfaces. The taper angle between the profile of the through-semiconductor via and the at least one of at least two essentially parallel surfaces is between 80 degrees and 89.9 degrees. The narrowest diameter of the through-semiconductor via has a dimension between 5 and 250 micrometers.

A method of forming a front-side illuminated, back-side contacted photodiode structure comprises forming a plurality of regions of a first conductivity type in a first surface of two essentially parallel surfaces of a semiconductor, forming a region of a single conductivity type in the second surface opposite to the first conductivity type, and forming a plurality of through-semiconductor vias, by performing reactive ion etching (RIE) part way through the semiconductor using an appropriate etch mask on the first of the two essentially parallel surfaces, followed by similar RIE etching using an appropriate etch mask on the second of the two essentially parallel surfaces, such second etch mask aligned to the first etch mask, wherein the cross-sectional profile of the through-semiconductor via has a varying taper angle with respect to each of the at least two semiconductor surfaces such that the diameter of the through-semiconductor via is at its narrowest at a location between the two essentially parallel surfaces, such that the plurality of such through-semiconductor vias can be used to make electrical contact to the plurality of regions of the first conductivity type on the first semiconductor surface, and wherein the sidewalls of such through-semiconductor via are subsequently lined with a dielectric material providing electrical insulation between the center region of the through-semiconductor via and the surrounding semiconductor, and wherein the center region of the through-semiconductor via is partially or completely filled with a conducting material.

The semiconductor comprises silicon. The plurality of regions of a first conductivity type are formed using ion implantation. The second surface of conductivity type opposite to the first conductivity type is formed by growing a single crystal silicon boule doped with the appropriate dopant for the opposite conductivity type. The first surface comprises an epitaxial layer of semiconductor grown on a single crystal semiconductor wafer. The appropriate etch mask comprises a layer of silicon dioxide, silicon nitride, and photoresist. The dielectric material is thermally grown silicon dioxide, a combination of thermally grown silicon dioxide and CVD deposited silicon dioxide, or a combination of thermally grown silicon dioxide and CVD deposited silicon nitride. The partially or completely filled conducting material comprises n-type polysilicon.

An x-ray detector system can be comprised of a plurality parallelpipeds of scintillator material bonded to a plurality of photodiode arrays having the photodiode structure according to an embodiment of the present invention. The plurality of parallelpipeds of scintillator material comprises gadolinium oxysulfide, cadmium tungstate, or cesium iodide. The plurality of parallelpipeds of scintillator material are bonded to the plurality of photodiode using optically transparent epoxy or silicone. The x-ray detector can comprise a computed tomography or a digital x-ray system using the photodiode array having the photodiode structure according to the present invention.

In summary, a semiconductor structure comprises a through-semiconductor via having an insulating lining isolating a conductive center region of the through-semiconductor via from the surrounding semiconductor, and wherein the cross-sectional profile of the through-semiconductor via has a varying taper angle such that the diameter of the through-semiconductor via is at its narrowest at a location between two essentially parallel surfaces of the semiconductor structure.

It is an advantage of the via of the present invention that the number of processing and deposition steps for the semiconductor structure can be reduced so that the total time and cost of processing can also be reduced. Further, a narrower via than those of the prior art can be realized. The density of the via without significant non-conductive voids can also be assured.

### DETAILED DESCRIPTION

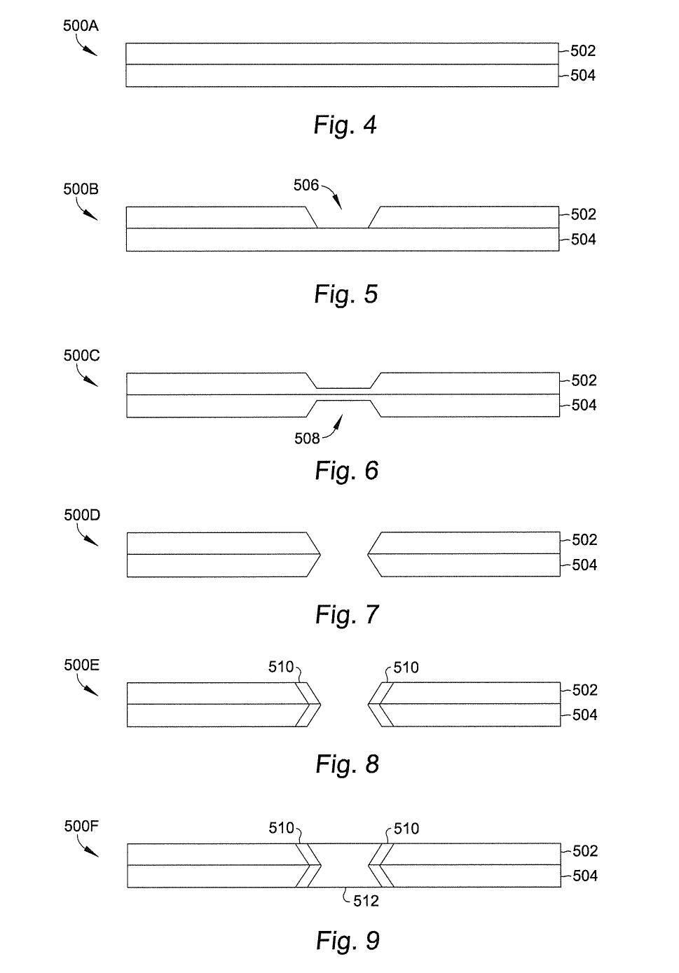

FIGS. 4-9 are cross-sectional views of a through-semiconductor via according to an embodiment of the present invention corresponding to sequential processing steps 500A through 500F.

FIG. 4 shows an example semiconductor structure 500A suitable for use in photodiode array, including a substrate 504 and an epitaxial layer 502.

FIG. 5 shows the semiconductor structure 500B at a second processing step wherein a first portion 506 of a via according to an embodiment of the present invention is etched out of the epitaxial layer 502.

FIG. 6 shows the semiconductor structure 500C at a third processing step wherein a second portion 508 of the via according to an embodiment of the present invention is partially etched out of the substrate 508.

FIG. 7 shows the semiconductor structure 500D at a fourth processing step wherein the via according to an embodiment of the present invention being completely etched through, having a first portion and a second portion, from the front-side of the semiconductor structure through to the back-side of the semiconductor structure.

FIG. 8 shows the semiconductor structure 500E at a fifth processing step wherein a thermally grown oxide layer 510 covers the sidewalls of the via according to an embodiment of the present invention.

FIG. 9 shows the semiconductor structure 500F at a sixth processing step wherein the via is filled with a conductive material 512.

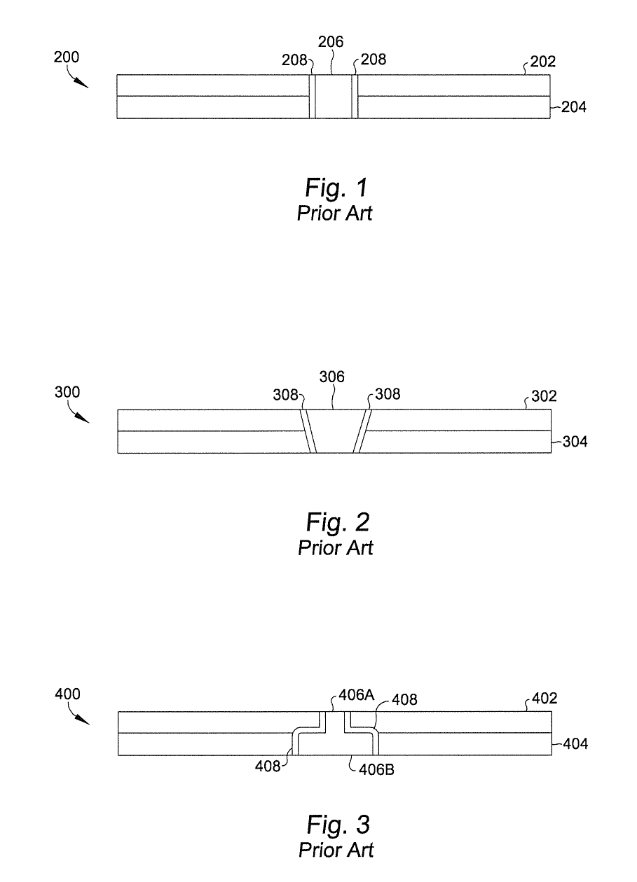

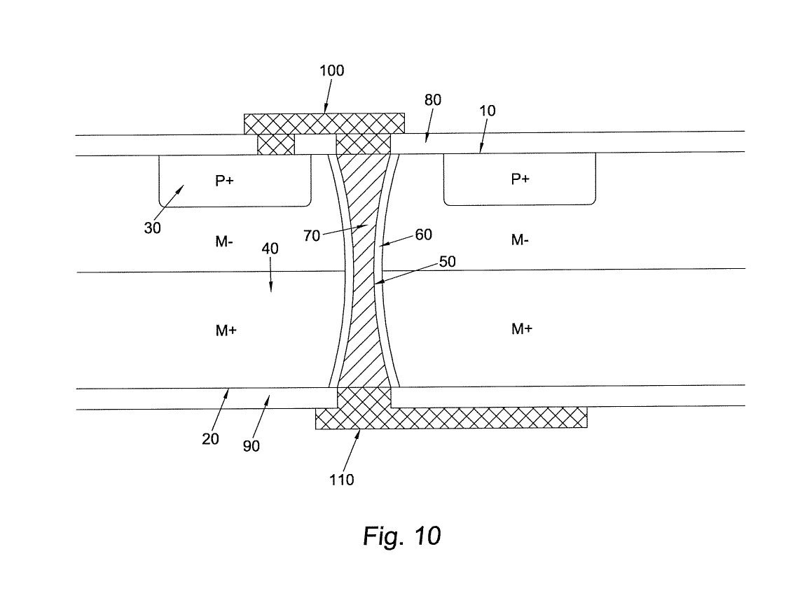

FIG. 10 is a cross-sectional view of a completed through-semiconductor via according to an embodiment of the present invention. The semiconductor structure has a first surface 10 and a second surface 20 parallel to the first surface. The epitaxial layer includes a plurality of regions 30 of a first conductivity type, show in FIG. 1 as p+ regions. The substrate layer 40 is of a second conductivity type, shown in FIG. 1 as an n+ layer. The conductive through-semiconductor via 50 is shown having a liner dielectric layer (typically a thermally grown oxide layer) 60. Via 50 is filled with a conductive material 70. Layer 80 is a dielectric layer on the first surface of the semiconductor structure. Layer 90 is a dielectric layer on the second surface of the semiconductor structure. Metal line 100 couples one of the p+ regions 30 to a first end of the filled via 50. Metal line 110 is coupled to a second end of the filled via 50.

FIGS. 4-10 illustrate an embodiment of a semiconductor structure including a through-semiconductor via according to the present invention. Numerous variations of the basic illustrated structure are possible. For example, while the via is shown being substantial symmetrical in both X and Y directions, this is not necessary. The length of the top portion of the via measured from the top-side surface can extend above or beyond the midpoint of the semiconductor structure. Likewise, the bottom portion of the via measured from the bottom-side surface can also extend above or beyond the midpoint of the semiconductor structure. While the via is shown having substantially similar taper angles, it will be apparent to those skilled in the art that the taper angle can be varied from those as shown, and two different taper angles can be used. While a thermally grown oxide layer is shown, other types of oxide and dielectric layers can be used to electrically isolate the center conductive material of the via. The manner in which the via can be filled is envisioned as having at least two steps to fill the via from the top and bottom. Other via-filling steps can be used. It will also be apparent to those skilled in the art that other, more sophisticated semiconductor structures can be used. The exact nature of all of the materials used and exact dimensions of the via structure can be altered as desired for a specific application.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

I claim:

1. A front-side illuminated, back-side contacted photodiode structure comprised of a semiconductor having two essentially parallel surfaces wherein at least one of the two essentially parallel surfaces has a plurality of regions of a first conductivity type, and wherein the second surface has a single region of a conductivity type opposite to the first surface, and wherein the said plurality of regions of the first conductivity type are electrically contacted by through-semiconductor vias having an insulating lining isolating the conductive center region of said through-semiconductor via from the surrounding semiconductor, and wherein the cross-sectional profile of said through-semiconductor via has a varying taper angle with respect to each of the two surfaces such that the diameter of said through-semiconductor via is at its narrowest at a location between the two essentially parallel surfaces.

2. The structure of claim 1 wherein the said semiconductor is comprised of one of the list of silicon, germanium, or gallium arsenide.

3. The structure of claim 1 wherein the said plurality of regions of a said first conductivity type are p-type and comprise a plurality of photodiode anodes.

4. The structure of claim 3 wherein the plurality of photodiode anodes are comprised of silicon doped with boron.

5. The structure of claim 1 wherein the said plurality of regions of a first conductivity type are n-type and comprise a plurality of photodiode cathodes.

6. The structure of claim 5 wherein the plurality of photodiode cathodes are comprised of silicon doped with a combination of arsenic and phosphorus.

7. The structure of claim 1 wherein the said single region of a conductivity type opposite to the first conductivity type is n-type and comprises a common photodiode cathode.

8. The structure of claim 7 wherein the said common photodiode cathode is comprised of silicon doped with a combination of arsenic and phosphorous.

9. The structure of claim 1 wherein the said single region of a conductivity type opposite to the first conductivity type is p-type and comprises a common photodiode anode.

10. The structure of claim 1 wherein the said conductive center region of said through-semiconductor via is comprised of n-type polysilicon.

11. The structure of claim 10 wherein the said n-type polysilicon is comprised of phosphorous doped polysilicon.

12. The structure of claim 1 wherein the said narrowest diameter of the said through-semiconductor via occurs at a location approximately equi-distant from the said two essentially parallel surfaces.

13. The structure of claim 1 wherein the said taper angle between the said profile of the said through-semiconductor via and the said at least one of at least two essentially parallel surfaces is between 80 degrees and 89.9 degrees.

14. The structure of claim 1 wherein the said narrowest diameter of the said through-semiconductor via has a dimension between 5 and 250 micrometers.

15. A method of forming a front-side illuminated, back-side contacted photodiode structure comprised of forming a plurality of regions of a first conductivity type in a first surface of two essentially parallel surfaces of a semiconductor, forming a region of a single conductivity type in the second surface opposite to the first conductivity type, and forming a plurality of through-semiconductor vias, by performing reactive ion etching (RIE) part way through the semiconductor using an appropriate etch mask on the first of the two essentially parallel surfaces, followed by similar RIE etching using an appropriate etch mask on the second of the two essentially parallel surfaces, such second etch mask aligned to the first etch mask, wherein the cross-sectional profile of the through-semiconductor via has a varying taper angle with respect to each of the at least two semiconductor surfaces such that the diameter of said through-semiconductor via is at its narrowest at a location between the two essentially parallel surfaces, such that the plurality of such through-semiconductor vias can be used to make electrical contact to the plurality of regions of the first conductivity type on the first semiconductor surface, and wherein the sidewalls of such through-semiconductor via are subsequently lined with a dielectric material providing electrical insulation between the center region of the through-semiconductor via and the surrounding semiconductor, and wherein the center region of the through-semiconductor via is partially or completely filled with a conducting material.

16. The method of claim 15 wherein the semiconductor comprises silicon.

17. The method of claim 15 wherein said plurality of regions of a first conductivity type are formed using ion implantation.

18. The method of claim 16 wherein the said second surface of conductivity type opposite to said first conductivity type is formed by growing a single crystal silicon boule doped with the appropriate dopant for said opposite conductivity type.

19. The method of claim 15 wherein the said first surface comprises an epitaxial layer of semiconductor grown on a single crystal semiconductor wafer.

20. The method of claim 16 wherein the said appropriate etch mask comprises a layer of silicon dioxide, silicon nitride, and photoresist.

21. The method of claim 16 wherein the said dielectric material is thermally grown silicon dioxide.

22. The method of claim 16 wherein the said dielectric material is a combination of thermally grown silicon dioxide and CVD deposited silicon dioxide.

23. The method of claim 16 wherein the said dielectric material is a combination of thermally grown silicon dioxide and CVD deposited silicon nitride.

24. The method of claim 16 wherein the said partially or completely filled conducting material comprises n-type polysilicon.

25. An x-ray detector system comprised of a plurality parallelpipeds of scintillator material bonded to a plurality of photodiode arrays having the structure of claim 1.

26. The x-ray detector system of claim 25 wherein the said plurality of parallelpipeds of scintillator material comprises one of a list of gadolinium oxysulfide, cadmium tungstate, or cesium iodide.

27. The x-ray detector system of claim 25 wherein the said plurality of parallelpipeds of scintillator material are bonded to the said plurality of photodiode arrays using one of the list of optically transparent epoxy or silicone.

28. A computed tomography system comprised of an x-ray detector system of claim 25.

29. A digital x-ray system comprised of an x-ray detector system of claim 25.

30. A semiconductor structure comprising a through-semiconductor via having an insulating lining isolating a conductive center region of said through-semiconductor via from the surrounding semiconductor, and wherein the cross-sectional profile of said through-semiconductor via has a varying taper angle such that the diameter of said through-semiconductor via is at its narrowest at a location between two essentially parallel surfaces of the semiconductor structure.
